(19) United States
(12) Patent Application Publication
(10) Pub. No.: US 2006/0073709 A1
(43) Pub. Date: Apr. 6, 2006

(54) High density midplane

(75) Inventor: Brian P. Reid, Harlow (GB)

Correspondence Address: Edmund J. Walsh;Wolf, Greenfield & Sacks, P.C., 600 Atlantic Avenue, Boston, MA, 02210-2206, US

(73) Assignee: Teradyne, Inc., Boston, MA (US)

(21) Appl. No.: 10/959,652

(22) Filed: Oct. 6, 2004

(51) Int. Cl. H05K 1/00

(52) U.S. Cl. 439/65

(57) ABSTRACT

An electronic system with multiple printed circuit boards interconnected through a midplane. Connectors are mounted on two sides of the midplane to facilitate connection of daughter cards from both the front and the back of the midplane. For cross-connecting coupling signals between daughter cards mounted to the front and daughter cards mounted to the back of the midplane, connectors mounted to the front and the back of the midplane are overlapped in certain regions. Within these regions, an efficient routing pattern is employed to cross-connect signals from the front of the midplane to the back of the midplane. The routing is achieved in a very small space but provides the desired impedance of the interconnects.

### BACKGROUND OF INVENTION

1. Field of Invention

This invention relates generally to electronic systems and more particularly to the interconnection of circuit boards in electronic systems.

2. Discussion of Related Art

Electronic systems are often assembled from multiple printed circuit boards. Each circuit board, which is sometimes called a “daughter card,” contains electronic components. The daughter card includes one or more electrical connectors that allow the circuits on the daughter card to be connected to other circuits in the system.

Often, electrical signals are routed from one daughter card to another through a backplane. A backplane is a printed circuit board with many conducting paths, called “traces” or “tracks.” Connectors are mounted on the backplane to make connection to the traces. When the connectors on the daughter cards are mated with the connectors on the backplane, signal paths are established between the daughter cards.

The portion of a printed circuit board that allows a trace to be connected to a contact element in a connector is called a “signal launch.” A signal launch is formed by drilling a hole through the circuit board. The hole passes through the signal trace or ground plane to which the signal launch is to be connected. The inside walls of the hole are plated with a conducting material, such as metal. The plating leaves a pad at the surface of the printed circuit board. A press fit contact tail is designed such that when it is inserted in the hole of the signal launch, it presses against the walls of the hole, making contact to the conductive plating. The conductive plating is electrically connected to any traces or ground layers that were drilled through to form the hole. In this way, the contact tail may be electrically connected to a trace within the printed circuit board.

An example of a connector that is suitable for use in connecting two circuit boards are shown in U.S. Pat. Nos. 6,409,543; 6,506,076; 6,592,381, and 6,602,095, which are hereby incorporated by reference. One connector commercially available for use in connecting printed circuit boards is the GbX® connector sold by Teradyne, Inc. of Nashua, N.H.

In electronic systems, it is often desirable for the system to be as compact as possible. Some systems use a “midplane” instead of a backplane. A midplane is also a printed circuit board with signal traces and connectors. However, a midplane has connectors on both sides, allowing daughter cards to be inserted in the front and the back of the midplane.

The midplane can route signals between boards inserted from the same side or can “cross-connect” a board inserted from one side and a board inserted from the other side. Where it is desired to cross-connect signals, midplanes have been constructed with contact tails from connectors on both sides of the midplanes inserted in the same hole. In this way, the contact tails of the two connectors are connected directly through the plating on the hole. An example of such a system is shown in U.S. Pat. No. 4,686,607.

Systems have also been constructed with connectors that have signal contact elements with one contact tail and two contact portions. The contact tail is mounted in the hole and one contact portion extends from each side of the midplane. In this way, cross-connections may be made directly through the contact element.

However, such systems are not well suited for cross-connecting differential signals because the pairs of conductors that form one differential signal cannot be adjacent in connectors on both sides of the midplane

It would, however, be desirable to provide improved cross connection of connectors mounted on two sides of a midplane, particularly a high density midplane and particularly for cross-connection of differential signals.

### SUMMARY OF INVENTION

In one aspect, the invention relates to an electronic system of the type having a midplane with connectors mounted on each side. Each connector has a plurality of contact tails connected to signal launches on the printed circuit board. Each signal launch includes a plated hole in the printed circuit board. The signal launches associated with contact tails of a first connector are disposed in rows and columns, and the signal launches associated with contact tails of a second connector are disposed in rows and columns. The rows and columns associated with the second connector at least partially overlap the rows and columns associated with the first connector, thereby forming an array of signal launches having a plurality of sub-arrays. Each sub-array has a first plurality of signal launches associated with the first connector and a like plurality of signal launches associated with the second connector. Within each sub-array, each of the first plurality of signal launches associated with the first connector is connected to one of the like plurality of signal launches associated with the second connector.

In another aspect, the invention relates to a midplane for an electronic system that has a first side and a second side; a plurality of signal launches; and a first electrical connector mounted on the first side having a plurality of signal contacts. Each signal contact has a contact tail connected to a signal launch. The signal launches coupled to contact tails of the first electrical connector form a first array in a first region. A second electrical connector is mounted on the second side. The second connector has a plurality of signal contacts, each signal contact having a contact tail connected to a signal launch. The signal launches coupled to contact tails of the second electrical connector form a second array in a second region. The first region and the second region partially overlap in a third region, with the third region comprising a plurality of sub-arrays. Each sub-array has a first plurality of pairs of signal launches from the first array and a second plurality of pairs in the second array. The signal launches in each pair of the first plurality of pairs are adjacent in the first array and the signal launches in each pair of the second plurality of pairs are adjacent in the second array. A plurality of pairs of traces within each sub-array connect one of the first plurality of pairs of signal launches to one of the second plurality of pairs of signal launches.

In another aspect, the invention relates to an electronic system that has a midplane with a first side and a second side. Midplane connectors mounted on the first side form a first plurality of elongated groups of connection points and midplane connectors mounted on the second side form a second plurality of elongated groups of connection points. A first plurality of daughter cards are installed in the system. Each daughter card has at least one daughter card connector mated with a connector in one of the first plurality of groups. A second plurality of daughter cards are installed in the system. Each daughter card has at least one daughter card connector mated with a connector in one of the second plurality of groups. A plurality of signal traces within the midplane connect connectors in the first plurality of elongated groups to connectors in the second plurality of elongated groups. Each of the first plurality of elongated groups is elongated in a first direction and each of the second plurality of elongated groups is elongated in a second direction orthogonal to the first direction and the groups are positioned to form regions of overlap of connectors in the first plurality of elongated groups and connectors in the second plurality of elongated groups and the plurality of signal traces are disposed in a repeating pattern in the regions of overlap.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a sketch of an electronic system constructed with a midplane;

FIG. 2A is a sketch of the back of the midplane in the system of FIG. 1;

FIG. 2B is a sketch of the front of the midplane in the system of FIG. 1;

FIG. 3 is a sketch of the pattern of signal launches for mounting a connector on a printed circuit board;

FIG. 4A is a sketch of the pattern of signal launches for mounting connectors on two sides of a printed circuit board;

FIG. 4B is a sketch showing a portion of the pattern of signal launches in FIG. 4A enlarged for greater clarity;

FIG. 4C is a sketch showing the interconnection of signal launches in FIG. 4B;

FIG. 5A is a sketch showing a first portion of the interconnections of FIG. 4C implemented on a first layer of a midplane; and

FIG. 5B is a sketch showing a second portion of the interconnections of FIG. 4C implemented on a second layer of a midplane.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

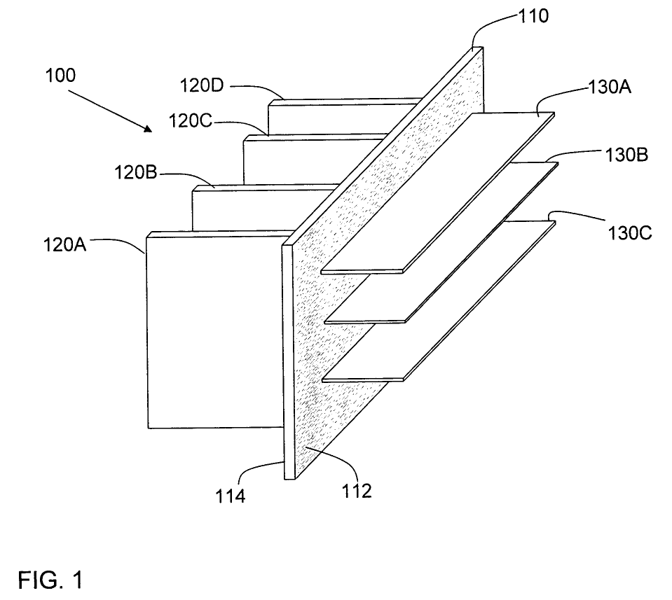

FIG. 1 is a sketch of an electronic system 100. Electronic system 100 is assembled with a midplane 110. Midplane 110 has a back 112 and a front 114.

Daughter cards 120A, 120B, 120C and 120D are inserted in midplane 110 from front side 114. Daughter cards 130A, 130B, 130C are inserted in midplane 110 from the back.

As in a conventional system, the daughter cards 120A, 120B, 120C, 120D and 130A, 130B and 130C contain the daughter card piece (not shown) of a two piece electrical connector. The mating piece of the electrical connector is mounted to midplane 110. To receive daughter cards from the front and the back, midplane 110 includes electrical connectors mounted on both the front 114 and back 112. Midplane 110 includes multiple traces that route signals between connectors attached to midplane 110. These traces may make connections between any two of the daughter cards mounted from the front, such as 120A, 120B, 120C and 120D. Likewise, the traces may connect any of the daughter cards mounted from the back, such as 130A, 130B or 130C. In addition, these traces may cross-connect the daughter cards mounted from the front with daughter cards mounted from the back.

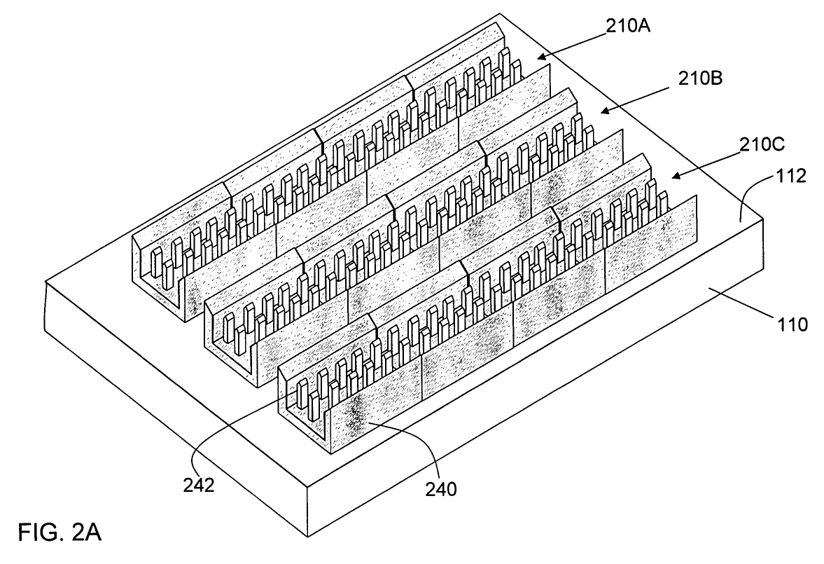

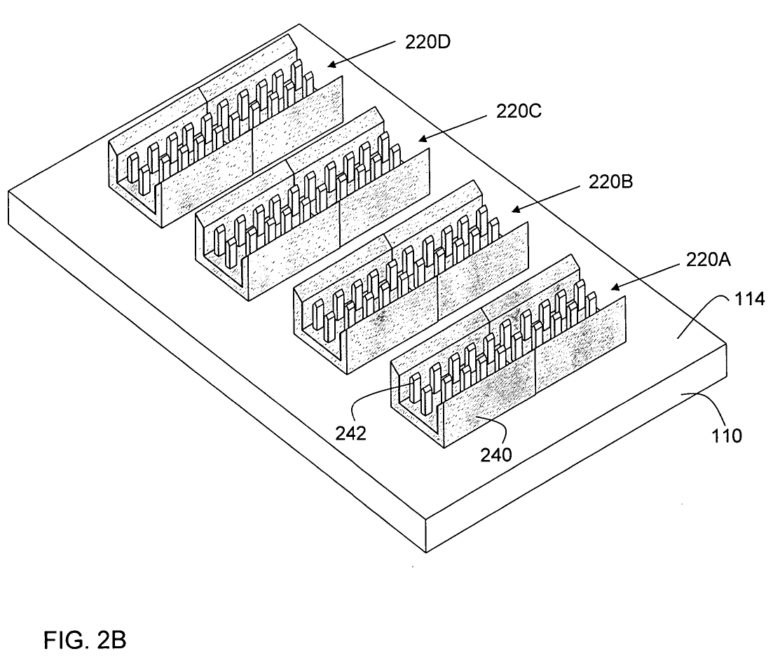

FIG. 2A shows a sketch of the back 112 of midplane 110. The back 112 of midplane 110 includes multiple rows 210A, 210B, 210C of electrical connectors. In the illustrated embodiment, each row is made up of multiple connector modules 240. The number of rows on the backside and the number of connector modules in each row is not critical to the invention. However, in one embodiment there is one row of connectors for each of the daughter boards to be mounted to midplane 110 from the back 112. Each row forms one connector that is elongated in the direction following the forward edge of a daughter card inserted into midplane 110 from the back. There will be a sufficient number of connector modules in each row to provide the required number of electrical connections between the midplane 110 and the corresponding daughter card.

Each connector module 240 includes multiple contact elements 242. Each contact element 242 includes a contact portion for making electrical connection to a corresponding connector in a daughter card connector. Each contact element 242 also includes a contact tail for making electrical connection through a signal launch to a trace within midplane 110. The number of contact elements in each connector module is not critical to the invention and connectors with a relatively small number of contact elements are illustrated for simplicity.

In the described embodiment, the contact elements in each connector module 240 are positioned in a rectangular array. In the described embodiments, the rectangular array is symmetrical. The contact elements 242 in the rows and columns of that rectangular array are equally spaced. In the example used herein, each contact element is spaced from an adjacent contact element in the same row by about 2.0 mm or less on center. Each contact element is spaced from an adjacent contact element in the same column by about 2.0 mm on center. In a specific example used herein, the spacing is about 1.85 mm in both the row and column direction.

FIG. 2B shows front 114 of midplane 110. Connectors are mounted in rows 220A, 220B, 220C, and 220D on the front 114 of midplane 110. As with the connectors mounted on the back, each row is formed from multiple connector modules 240. Each connector module contains multiple contact elements 242. Preferably, midplane 110 contains one row of connectors for each daughter card 120A, 120B, 120C, and 120D installed from the front. The rows 220A . . . 220D are similar to rows 210A, 210B and 210C, but are mounted orthogonal to these rows to create a region of overlap between each row on the front and each row on the back.

FIGS. 2A and 2B show the rows 210A, 210B, 210C or 220A, 220B, 220C and 220D on the same side of midplane 110 with the same number of connector modules 240 and the same number of contact elements in each module. The actual number of connector modules and contact elements used to form each row will depend on the design of the daughter card to be connected to midplane 110 through the connector in that row. Accordingly, some rows will have more or fewer connector modules. Further, some rows may have spacing between connector modules.

Further, FIGS. 2A and 2B show connector modules 240 each having arrays of identical contact elements. Some contact elements may be used for shielding such as is illustrated in the above referenced U.S. Pat. Nos. 6,409,543; 6,506,076; 6,592,381, and 6,602,095, and might therefore be shaped differently than the other contact elements. Such details of the construction of the connectors are not critical to the invention and are not shown for simplicity.

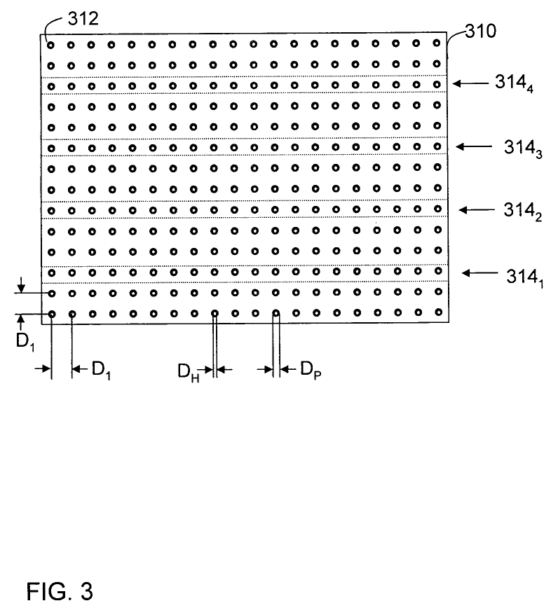

FIG. 3 shows the mounting footprint 310 for connector modules such as modules 240. Footprint 310 is made up of multiple signal launches 312. Each signal launch 312 is positioned to be aligned with and electrically connected to a contact tail from a contact element 242. FIG. 3 shows that footprint 310 has 14 rows of signal launches 312. Footprint 310 is shown to have twenty columns of signal launches 312. This configuration corresponds to two modules of the above referenced commercially available GbX® connector in the five pair configuration.

The GbX® connector is adapted for carrying differential signals. A differential signal is carried on a pair of conductors. In the illustrated configuration, each column of signal launches 312 is divided into pairs of two conductors spaced by a signal launch connected to ground. Rows 314₁, 314₂, 314₃, 314₄ represent rows of signal launches that may be connected to ground to provide electrical isolation between pairs in a column. In systems using the GbX® connector, the signal launches in rows 314₁, 314₂, 314₃, 314₄ may be connected to dedicated shields or grounds within a connector. Signal launches 312 may be formed as is known in the art. For connectors that have press fit contact tails, signal launches are often formed as plated through holes.

The holes used to form each signal launch 312 have a diameter D_{H}. The pads have a diameter D_{P}. In the described embodiment, D_{H} is less than 0.5 mm. As a specific example, D_{H} may be about 0.45 mm. The distance D_{P} is preferably greater than 0.85 mm and is more preferably greater than 0.88 mm. As a specific example, D_{P} may be about 0.9 mm.

FIG. 3 shows signal launches 312 positioned in a rectangular array with rows and columns that have equal spacings between the signal launches. The center to center distance, or the on center spacing, of the signal launches is D_{I}. Preferably, D_{I} is smaller than 2 mm. As a specific example, the distance D_{I} is about 1.85 mm.

FIG. 3 illustrates a footprint 310 which may correspond to the signal launches needed to make connections to connectors in a portion of any of the rows such as 220A . . . 220D or 210A . . . 210C. Because the rows 210A, 210B, 210C on back 112 are orthogonal to the rows 220A, 220B, 220C, 220D on front 114 of midplane 110, there will be regions of the midplane where each row on the back intersects each row on the front. Where cross-connections are desired between a board on the front and a board on the back, the cross-connections may be conveniently made in these regions of overlap.

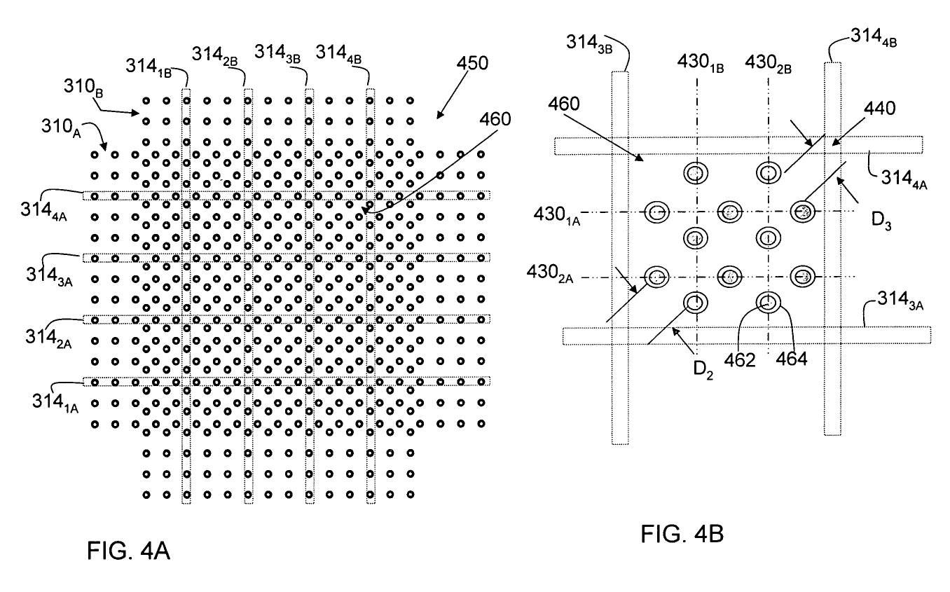

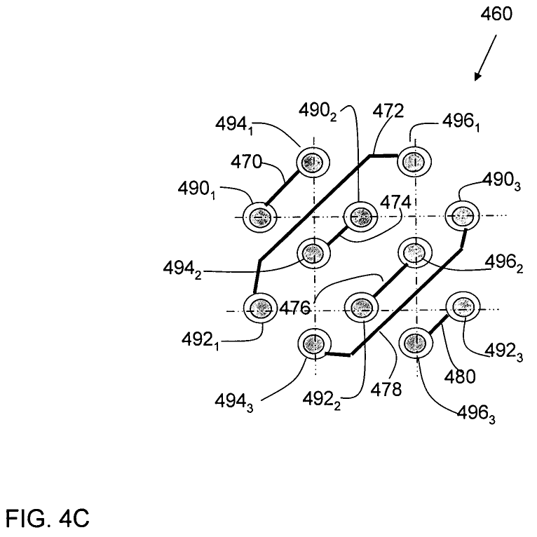

FIG. 4A shows a footprint 450 in one of these regions of overlap. Footprint 450 is made of the superposition of a footprint 310A, which might correspond to the footprint of a connector mounted to the back of midplane 110, with the footprint 310B, which might correspond to a connector mounted to the front of midplane 110. A large number of holes associated with the signal launches exist in the region of overlap, leaving very little space in footprint 450 for routing signal traces for cross-connecting the connectors. Furthermore, the specific dimensions and routing locations of those signal traces must be selected to ensure desired electrical properties of the cross-connects.

FIG. 4A shows that the ground rows 314_{1A}, 314_{2A}, 314_{3A} and 314_{4A} associated with footprint 310A combined with the ground rows 314_{1B}, 314_{2B}, 314_{3B}, and 314_{4B} of footprint 310B define regions such as 460. One of the regions 460 is shown in greater detail in FIG. 4B. Here the region 460 is shown to contain 12 signal launches. Six of the signal launches are associated with footprint 310B.

FIG. 4B shows that region 460 includes a portion of a row 430_{1A} and 430_{2A} from connector footprint 210A. The region 460 simultaneously includes portions from row 430_{1B} and 430_{2B} associated with footprint 310B. Because these signal launches result from superimposing footprints from two separate connectors, the spacing between the signal launches is now smaller than the spacing with footprint 310 representing the footprint of a single connector. Within region 460 the minimum on center spacings between any two signal launches is represented as D₂. The distance D₂ is in the example given herein 1.31 mm. This spacing is preferably sufficient to route traces between the holes. As a result, there are diagonal routing channels, such as 440. In the illustrated embodiment, these routing channels are at a 45° angle to the rows that make up the connector footprints 310_{A} and 310_{B}.

Each signal launch is shown to have a hole 462 and a pad 464. The spacing between pads of adjacent signal launches is illustrated as D₃. In the example given herein, D₃ is 0.41 mm.

In the illustrated embodiment, the connectors are designed to carry differential signals. Accordingly, the 12 signal launches correlate to three differential signals routed between back 112 and front 114. Preferably, the two legs of a differential signal are routed, over substantially all of their length, adjacent to each other. Further, the characteristics of the conducting paths carrying the two legs of a pair should be substantially the same. An advantage of the cross-connect system described herein is that such routing is preserved in midplane 110.

In the described embodiment, a signal launch in row 430_{1A} and the adjacent signal launch in row 430_{2A} form one differential pair. Thus, signal launches in rows 430_{1A} and 430_{2A} connect to three differential pairs in a connector mounted to back 112. Likewise, each signal launch in row 430_{1B} and the adjacent signal launch in row 430_{2B} forms one differential pair. Signal launches in rows 430_{1B} and 430_{2B} connect to form three differential pairs in a connector on front 114. Traces in midplane 110 interconnect the signal launches in region 460 so that adjacency of legs forming a pair of a differential signal is preserved through midplane 110.

FIG. 4C illustrates that each signal launch in the footprint 310A (FIG. 4A) may be connected in region 460 to a corresponding signal launch in footprint 310B (FIG. 4A). Trace 470 connects signal launch 490₁ to signal launch 494₁. Trace 472 connects signal launch 492₁ to signal launch 496₁. Trace 474 connects signal launch 494₂ to signal launch 490₂. Trace 476 connects signal launch 492₂ to signal launch 496₂. Trace 478 connects signal launch 494₃ to signal launch 490₃. Trace 480 connects signal launch 496₃ to signal launch 492₃. In this way, the adjacency of signals launches that carry legs of differential pairs is preserved. The pair made up of signal launches 490₁ and 492₁, on the back are coupled to signal launches 494₁ and 496₁, which are adjacent on the front. Likewise, the pair 490₂ and 492₂ is coupled to 494₂ and 496₂. The pair 490₃ and 492₃ is coupled to 494₃ and 496₃.

In the embodiment of FIG. 4C, each of the signal launches is connected to another signal launch offset at an angle of 45° relative to the rectangular arrays of the signal launches that define footprint 310A or 310B. In this way traces connecting the signal launches within region 460 may run in the routing channels such as 440 illustrated in FIG. 4B.

Further, the routing configuration shown in FIG. 4C can be efficiently implemented. For example, traces 470, 472, 474, 476 and 478 might be implemented in only a single routing layer in a printed circuit board forming midplane 110. However, in the illustrated embodiment, two routing layers are used for improved electrical performance. Two routing layers used for cross-connects in a midplane also represents an efficient structure.

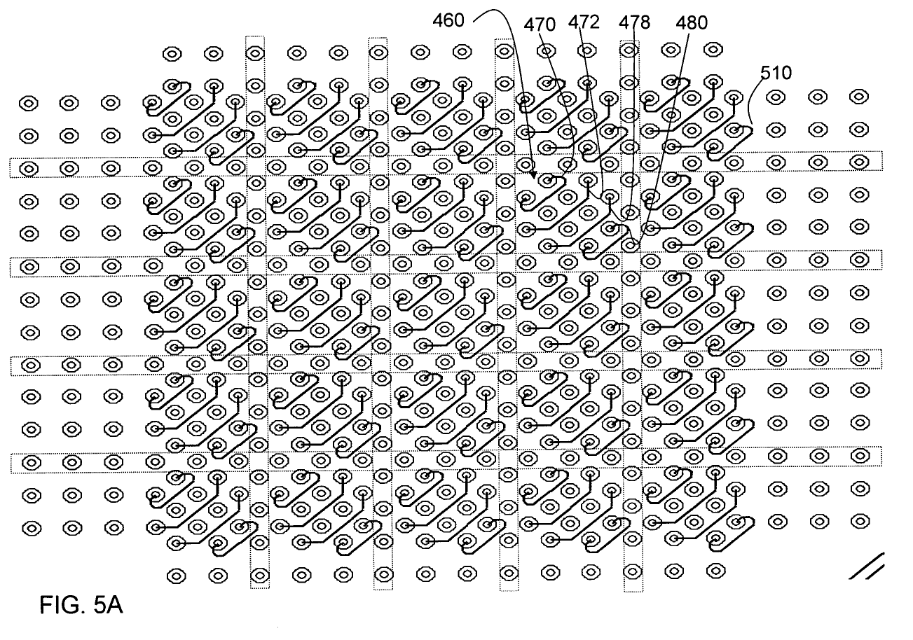

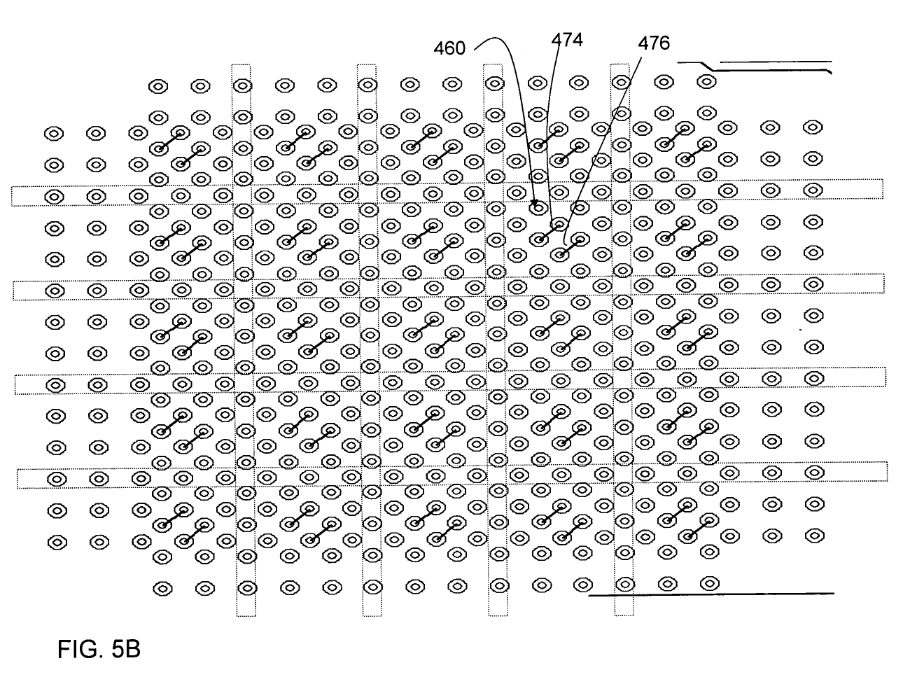

FIG. 5A shows a first routing layer. Traces 470, 472, 478 and 480 are implemented in a single routing layer. As illustrated in connection with FIG. 4C, traces 470 and 472 connect signal launches that are different legs of one differential pair. In the layout of FIG. 5A, these traces are adjacent, on the same routing layer and parallel over much of their length. They are not separated by a trace carrying a signal from another pair.

Traces 478, and 480 connect signal launches that carry signals of another differential pair. They likewise have the same relationship. Furthermore, FIG. 5A shows that for each pair, the distance between two of the signal launches is shorter than the distance between the other two signal launches. Specifically, signal launches 490₁ and 494₁ are closer together than signal launches 49₁ , and 496₁. Likewise, 492₃ and 496₃ are closer together than 490₃ and 494₃. To preserve the balance between legs of the pair, traces 470 and 480 are formed with curved portions, such as 510, that lengthen those traces so that they have a length similar to traces 472 and 478.

FIG. 5B shows a second routing layer. Traces 474 and 476 are shown implemented in the second routing layer. Traces 474 and 476 connect signal launches that carry the two legs of the third differential signal that may be cross-connected through region 460. As with the traces on the layers shown in FIG. 5A, these traces are adjacent, parallel across a substantial part of their length, not separated by the other traces, and of roughly the same length.

As illustrated in FIGS. 5A and 5B, this routing pattern is repeated across the entire region of overlap between footprints 310A and 310B. In this way, all of the signal conductors in the region of overlap may be used for cross coupling signals from aboard on the front side of midplane 110 between a board on the backside of midplane 110.

The midplane described above provides an efficient way to cross couple daughter cards mounted on opposing sides of a midplane. Advantageously, it provides for cross-connection of numerous signals in the relatively small space. In addition, the signal traces can be sized and spaced to provide desired impedance properties for the connections between signal launches. In a contemplated embodiment, single ended signals should be transmitted on lines having an impedance of approximately 50Ω. Differential signals should be transmitted on pairs having an impedance of approximately 100Ω. These configurations may be achieved with a midplane 110 constructed with FR4 cores and prepreg layers having a stack up of 0.13 mm to approximately 0.17 mm. In one contemplated embodiment the trace width is 0.135 mm.

In one contemplated embodiment, all traces are designed to have a nominal impedance of 50Ω. If two traces are used to carry a differential signal, they form a loosely coupled differential pair, which will have an impedance of approximately 100Ω. In one contemplated embodiment, the stack up is 0.15 mm. Traces are made with one ounce copper and have a width of 0.16 mm or less. The spacing between traces may be 0.406 mm or greater. With these dimensions, a midplane having a thickness of less then 9 mm, more preferably less than 6 mm, may be constructed and provide single ended trace impedances between about 45Ω and 55Ω and differential impedances between about 90 and 110Ω.

Having thus described several aspects of at least one embodiment of this invention, it is to be appreciated various alterations, modifications, and improvements will readily occur to those skilled in the art.

For example, a system 100 is illustrated having the daughter cards inserted from the back and fourth daughter cards inserted from the front. This number is an example only. Many systems are likely to have a larger number of boards.

Also, the term “daughter card” is used. Daughter cards are often referred to as daughter boards, mother cards or mother boards. The specific term used sometimes depends on the function or application of the board or system. The invention is not limited in its usefulness to any particular function or application of the daughter card.

As another example, holes are described as plated through holes. The holes need not extend entirely through the printed circuit board. Blind vias may be used. Further, the plating in each hole need not be a thin coating. The coating might fill the entire hole, creating a “pad” on the surface of the board to which a contact tail might be soldered.

Also, the structure of midplane 110 as described above is well suited for use in connection with a GbX® connector. Such a connector is available in modules having columns of signal contacts sufficient to provide five pairs for differential signals and four ground connections interspersed between the signal pairs. That connector also has a symmetrical pattern of contact tails providing the same amount of spacing between contact tails in the row and column direction, thereby facilitating overlapping of connector footprints such as is shown in FIG. 4A. As illustrated in FIG. 5, such a connection provides 25 regions 460, each providing cross-connections for three differential signals, or a total of 75 cross-connected differential signals or 150 single ended signals. However, other connectors might be used instead. For example, connectors providing only 4, 3, or 2 pairs per column might be used.

Also, FIG. 4A shows multiple sub-arrays of signal launches in regions 460. All of the regions 460 are shown to be identical. The number of cross-connections between boards mounted to the front of midplane 110 and the back of midplane 110 will depend on the structure and function of each board. Accordingly, every region 460 available for cross-connecting signals needs not be used for cross-connecting signals.

Such alterations, modifications, and improvements are intended to be part of this disclosure, and are intended to be within the spirit and scope of the invention. Accordingly, the foregoing description and drawings are by way of example only.

What is claimed is:

1. An electronic system of the type having a midplane with connectors mounted on each side, each connector having a plurality of contact tails, each tail connected to a signal launch on the printed circuit board, and each signal launch comprising a plated hole in the printed circuit board, wherein the signal launches associated with contact tails of a first connector are disposed in rows and columns, and the signal launches associated with contact tails of a second connector are disposed in rows and columns, the rows and columns associated with the second connector being at least partially overlapping the rows and columns associated with the first connector, thereby forming an array of signal launches having a plurality of sub-arrays, each sub-array having a first plurality of signal launches associated with the first connector and a like plurality of signal launches associated with the second connector and wherein, within each sub-array, each of the first plurality of signal launches associated with the first connector is connected to one of the like plurality of signal launches associated with the second connector.

2. The electronic system of claim 1 wherein each signal launch associated with the first connector is in both a row and a column and the on center spacing between each signal launch and an adjacent signal launch in the same row is equal to the on center spacing between said signal launch and an adjacent signal launch in the same column.

3. The electronic system of claim 2 wherein the on center spacing between adjacent signal launches in the same row is less than or equal to 2 mm.

4. The electronic system of claim 3 wherein the on center spacing between adjacent signal launches in the same row is less than or equal to 1.85 mm.

5. The electronic system of claim 3 wherein, within each sub-array, the on center spacing between a signal launch associated with the first connector and an adjacent signal launch associated with the second connector is less than or equal to 1.5 mm.

6. The electronic system of claim 3 wherein, within each sub-array, the on center spacing between a signal launch associated with the first connector and an adjacent signal launch associated with the second connector is less than or equal to 1.35 mm.

7. The electronic system of claim 1 wherein:
a) the on center spacing between adjacent signal launches in the same row associated with the first and the second connector is less than or equal to 2 mm;
b) the on center spacing between adjacent signal launches in the same column associated with the first and the second connector is less than or equal to 2 mm;
c) within each sub-array, the on center spacing between a signal launch associated with the first connector and an adjacent signal launch associated with the second connector is less than or equal to 1.5 mm.

8. The electronic system of claim 7 wherein each signal launch comprises a hole in the midplane having a diameter less than or equal to 0.6 mm.

9. The electronic system of claim 8 wherein each signal launch has a metal pad surrounding the hole and the pad has a diameter of 1 mm or less.

10. The electronic system of claim 1 wherein, within each sub-array, each of the first plurality of signal launches associated with the first connector is connected to one of the like plurality of signal launches associated with the second connector with a signal trace in the midplane.

11. The electronic system of claim 10 wherein the signal traces joining signal launches in each sub-array are disposed on a maximum of two routing layers within the midplane.

12. The electronic system of claim 1 wherein, within each sub-array, each of the first plurality of signal launches associated with the first connector is connected to one of the like plurality of signal launches associated with the second connector with a signal trace in the midplane having a portion oriented at a 45 degree angle to the rows of signal launches associated with the first connector.

13. The electronic system of claim 1 wherein, within each subarray, all of the signal launches in a row associated with the first connector are connected to signal launches in one row associated with the second connector.

14. The electronic system of claim 13 wherein each subarray, the signal launches in the row associated with the first connector have an order and the signal launches in the row associated with the second connector have the same order.

15. The electronic system of claim 1 wherein each subarray has twelve signal launches.

16. The electronic system of claim 1 wherein each sub-array is bounded by at least three lines of signal launches connected to ground.

17. A midplane for an electronic system comprising:
a) a first side and a second side;
b) a plurality of signal launches;
c) a first electrical connector mounted on the first side having a plurality of signal contacts, each signal contact having a contact tail connected to a signal launch, whereby the signal launches coupled to contact tails of the first electrical connector form a first array in a first region;
d) a second electrical connector mounted on the second side having a plurality of signal contacts, each signal contact having a contact tail connected to a signal launch, whereby the signal launches coupled to contact tails of the second electrical connector form a second array in a second region, the first region and the second region partially overlapping in a third region, with the third region comprising a plurality of sub-arrays, each sub-array having a first plurality of pairs of signal launches from the first array and a second plurality of pairs in the second array, wherein the signal launches in each pair of the first plurality of pairs are adjacent in the first array and the signal launches in each pair of the second plurality of pairs are adjacent in the second array; and
e) a plurality of pairs of traces within each sub-array, each pair connecting one of the first plurality of pairs of signal launches to one of the second plurality of pairs of signal launches.

18. The midplane of claim 17 wherein the first array of signal launches and the second array of signal launches comprise a rectangular array with rows and columns of signal launches, with signal launches in the rows and columns being equally spaced by a distance of 2 mm or less.

19. The midplane of claim 18 wherein each signal launch comprises a through hole having a conductive plating thereon and a conductive pad disposed on a surface of the midplane electrically connected to the plating.

20. The midplane of claim 17 wherein each of said traces in each sub-array has an impedance to single ended signals of 45 to 55 Ω.

21. The midplane of claim 20 wherein the midplane is made from dielectric layers having a stack up between 0.13 mm and 0.17 mm.

22. The midplane of claim 17 wherein the said pairs of traces in each sub-array have an impedance to differential signals of 90Ω to 110Ω.

23. The midplane of claim 22 wherein the spacing between traces of a pair is greater than or equal to 0.4 mm.

24. The midplane of claim 17 wherein for each of the plurality of pairs of traces both traces have approximately equal length.

25. The midplane of claim 17 wherein the midplane comprises at least a first routing layer and a second routing layer and each sub-array comprises three pairs of traces, with two pairs of traces disposed on the first routing layer and one pair of traces disposed on the second routing layer.

26. The midplane of claim 17 wherein the traces of each of the plurality of pairs of traces are adjacent.

27. The midplane of claim 17 wherein each signal launch in the first array is spaced on center from an adjacent signal launch in the first array by 2 mm or less.

28. An electronic system comprising:
a) a midplane having a first side and a second side with a plurality of midplane connectors mounted on the first side to form a first plurality of elongated groups of connection points and a plurality of midplane connectors mounted on the second side to form a second plurality of elongated groups of connection points;
b) a first plurality of daughter cards each having at least one daughter card connector thereon, the at least one daughter card connector on each of the plurality of daughter cards mated with a connector in one of the first plurality of groups;
c) a second plurality of daughter cards each having at least one daughter card connector thereon, the at least one daughter card connector on each of the plurality of daughter cards mated with a connector in one of the second plurality of groups;
d) a plurality of signal traces within the midplane connecting connectors in the first plurality of elongated groups to connectors in the second plurality of elongated groups;
e) wherein each of the first plurality of elongated groups is elongated in a first direction and each of the second plurality of elongated groups is elongated in a second direction orthogonal to the first direction and the groups are positioned to form regions of overlap of connectors in the first plurality of elongated groups and connectors in the second plurality of elongated groups and the plurality of signal traces are disposed in a repeating pattern in the regions of overlap.

29. The electronic system of claim 28 wherein each elongated group of connection points is formed from a plurality of connector modules.

30. The electronic system of claim 29 wherein each connector module has an array of contact tails positioned in rows and columns, with the on center spacing between contact tails in each row and each column being less than 2 mm.

31. The electronic system of claim 30 wherein the midplane is a printed circuit board having a stack-up between about 0.13 mm and 0.17 mm.

32. The electronic system of claim 31 wherein the width of each trace is less than about 0.2 mm.

33. The electronic system of claim 31 wherein the midplane has a plurality of layers of insulative material and the insulative material comprises FR4.

34. The electronic system of claim 30 wherein the midplane has a plurality of signal launches, each connected to a contact tail and at least one of the plurality of signal traces, each signal launch comprising a hole and a pad with the on center spacing between a signal launch connected to a contact tail from a connector in one of the first plurality of elongated groups and a signal launch connected to a contact tail from a connector in one of the second plurality of elongated groups is less than about 1.35 mm
